(19) United States
(12) Patent Application Publication
(10) Pub. No.: US 2026/0096463 A1
(43) Pub. Date: Apr. 2, 2026

(54) BUILD UP BONDING LAYER PROCESS AND STRUCTURE FOR LOW TEMPERATURE BONDING

(71) Applicant: ADEIA SEMICONDUCTOR BONDING TECHNOLOGIES INC., San Jose, CA (US)

(72) Inventors: Gaius Gillman Fountain, JR., Youngsville, NC (US); Pawel Mrozek, San Jose, CA (US); George Carlton Hudson, Wendell, NC (US)

(21) Appl. No.: 18/899,372

(22) Filed: Sep. 27, 2024

(51) Int. Cl. H01L 23/00

(52) U.S. Cl. CPC H10W 72/90; H10W 72/019; H10W 72/01938; H10W 72/01951; H10W 72/923; H10W 72/952; H10W 72/953; H10W 80/102; H10W 80/312; H10W 80/327; H10W 90/792; H10W 90/794; H10W 99/00

(57) ABSTRACT

Disclosed herein are methods of forming a microelectronic component. In some embodiments, the method includes providing a substrate, forming a metal feature over the substrate, forming an organic dielectric layer over the element such that the organic dielectric layer covers sidewalls of the metal feature, forming an inorganic dielectric material over the organic dielectric layer, and planarizing the inorganic dielectric material, the organic dielectric layer, and the metal feature. The planarized surface can serve as a hybrid bonding surface. The metal feature is exposed at the hybrid bonding surface.

### BACKGROUND

### Field

This application relates to direct bonding methods and structures, and more particularly to hybrid bonding methods and structures.

### Description of the Related Art

Microelectronic elements, such as integrated device dies or chips, may be directly bonded to other elements, thereby forming a bonded structure. Direct bonding can be conducted at low temperatures and without external pressure. Hybrid bonding involves directly bonding non-conductive features (e.g., inorganic dielectrics) of different elements together, without intervening adhesives, while also directly bonding conductive features (e.g., metal pads) of the elements together. A microelectronic element, such as an integrated device die or wafer, can be bonded to a carrier, such as a wafer, an interposer, a reconstituted wafer, panel or other element. As another example, a first integrated device die can be stacked on a second integrated device die. Each of the microelectronic elements can have conductive features, such as contact pads, for mechanically and electrically bonding the elements to one another. These conductive features are typically formed as part of a direct bonding layer formed on the surface of a metallization layer of the microelectronic elements.

Due to its conductivity, copper is the most common metal in state-of-the-art integrated circuit fabrication. Copper has challenges, such as the difficulty of dry etching copper to produce reliable patterns. For this reason, copper is often patterned by damascene processing, involving the patterning of insulators with trenches, overfilling them with plated copper, and polishing them back to the trench confines.

Other difficulties presented by copper include its high diffusivity in common insulators, such that it can poison semiconductor devices, and its poor adhesion to common insulators, such as silicon oxide based materials, Accordingly, copper features are often lined with adhesion and barrier materials that promote adhesion between copper and the surrounding insulator and prevent copper atoms from the conductive pads from diffusing into the surrounding dielectric material during the process of forming the bonding layer. In a damascene process, the adhesion and barrier materials can be lined in the trench before copper fill. These processes and materials can increase the cost of metallization process and can complicate processing.

Accordingly, there is a continuing need for improved methods for forming bonded structures at lower costs.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2 is a flowchart illustrating a process of processing and a hybrid bonding a microelectronic element, according to some embodiments.

FIGS. 3A-3G are schematic side sectional views of microelectronic elements at various blocks of a process like that shown in in FIG. 2.

FIG. 4 is a flowchart illustrating a process of forming a bonded structure, according to some embodiments.

FIGS. 5A and 5B are schematic side sectional views of microelectronic elements at various blocks of a process like that shown in FIG. 4.

FIG. 6 is a flowchart illustrating a process of forming a bonding layer on a substrate, according to some embodiments.

FIGS. 7A-7I are schematic side sectional views of microelectronic elements at various blocks of a process like that shown in FIG. 6.

FIG. 8 is a flowchart illustrating a process of forming a bonding layer on a substrate that includes through-substrate vias (TSVs), according to some embodiments.

FIGS. 9A-9D are schematic side sectional views of microelectronic elements at various of a process like that shown in FIG. 8.

### DETAILED DESCRIPTION OF THE PREFERRED EMBODIMENT

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Ser. No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

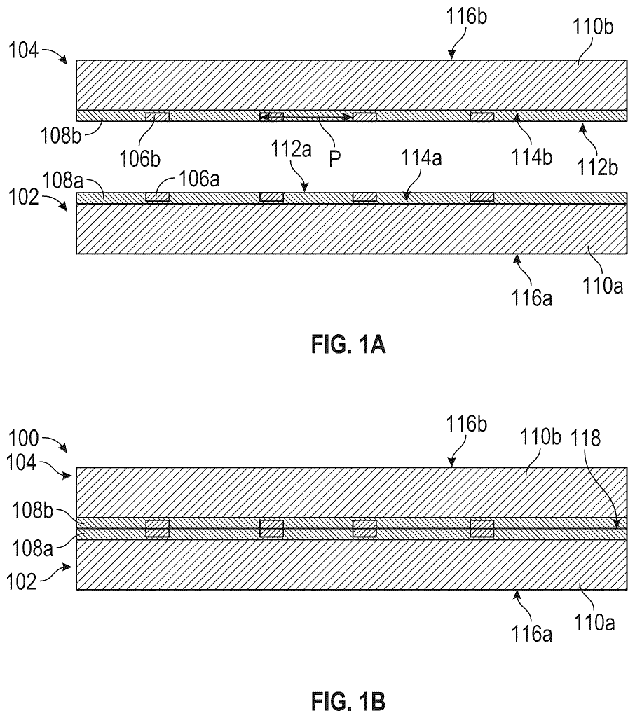

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxycarbonitride, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly through etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As noted in the Background above, copper conductive features for hybrid bonding layers are typically formed using a damascene process. In damascene processes, a dielectric layer is formed and then patterned to form openings in the dielectric layer. An adhesion/barrier layer is deposited in the openings and then copper is deposited over the adhesion/barrier layer. The adhesion/barrier layer is typically a metal-containing conductive material designed to prevent the copper metal from diffusing into the dielectric material during the deposition process and also to improve adhesion between the sidewalls of the opening and the copper metal. For example, the adhesion/barrier layer can comprise titanium (Ti), tantalum (Ta), such as elemental Ti metal, elemental Ta metal, TiN, TaN, combinations of the same, or other metal nitrides.

After depositing the copper metal, a CMP process is then performed to form a bonding surface suitable for hybrid bonding. In some embodiments, a multi-step CMP process is used due to differences in removal rate for the different material. For example, a first CMP process is performed using a first slurry for bulk overburden removal. The first slurry is typically tuned to copper removal and to permit stopping on the barrier material. Once the barrier on the upper surface is exposed, a second CMP process is typically performed using a second slurry chemistry, where the second slurry chemistry tends to remove copper, barrier and surrounding insulator materials at roughly the same rate. In this second CMP process, the barrier layer and copper metal are polished until they are coplanar with (or recessed below) the non-conductive surface of the dielectric material. Using two different slurry chemistries (and two different polishing pads) increases the complexity and costs of performing hybrid bonding.

Accordingly, there is a continued need for improved hybrid bonding processes that do not employ a multi-step CMP process with two slurry chemistries (and two different polishing pads).

After forming the bonding surface, the element can be hybrid bonded to a second element having a hybrid bonding surface by bringing the bonding surfaces of the two elements together, which can cause direct bonding between the non-conductive surfaces of the hybrid bonding surfaces. As previously described, the conductive features of one or both of the elements can be recessed below the non-conductive surfaces such that, when the two hybrid bonding surfaces are initially brought together, the conductive features on the opposing elements are separated from each other by a gap. To cause the conductive features to contact each other, the elements can be annealed to cause the conductive features to expand and contact one another to form a metal-to-metal direct bond. The barrier/adhesion layer(s) between the dielectric material and the copper metal, noted above with respect to damascene copper features, can constrain the expansion of the copper metal because the copper metal can remain adhered to the surrounding insulator by way of the barrier/adhesion layer(s). To ensure that the copper features on the opposing elements contact each other, the annealing temperature is typically sufficiently high to allow the copper to plastically deform to overcome adhesion to the surrounding materials and expand into contact with one another. However, annealing at too high of a temperature can degrade the performance of the bonded structure due to exceeding the thermal budget of the elements and/or the bonded structure.

Accordingly, there is a continued need for improved hybrid bonding processes that allow for annealing at lower temperatures.

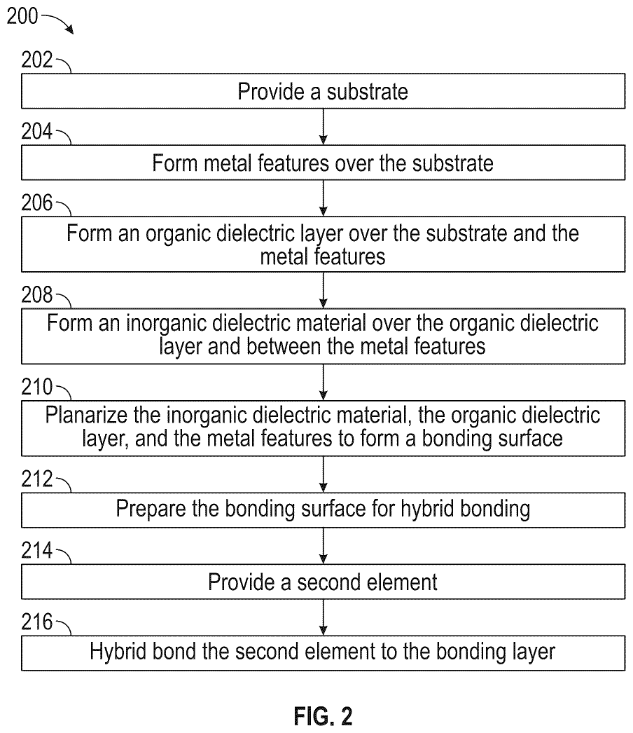

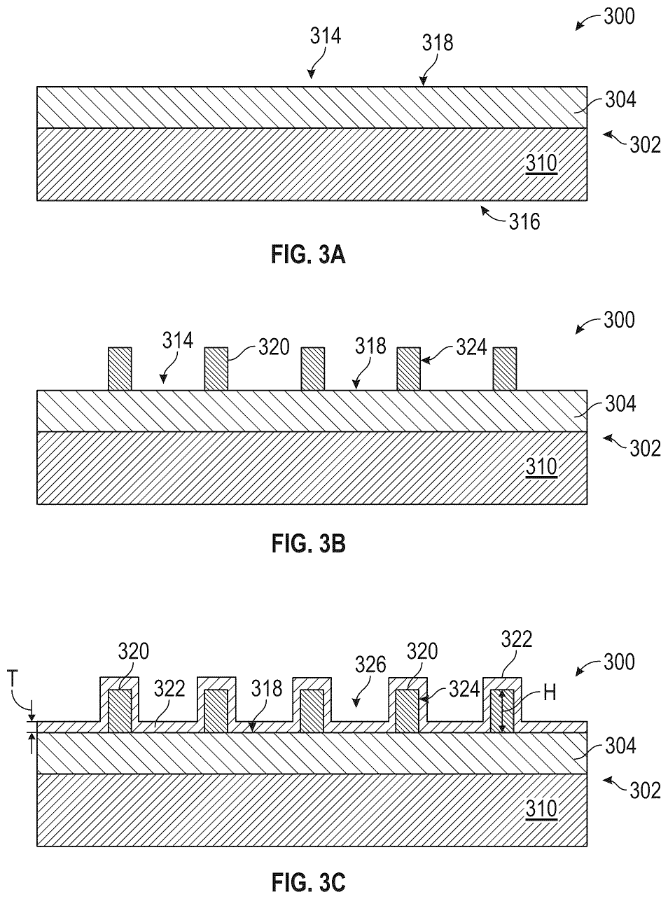

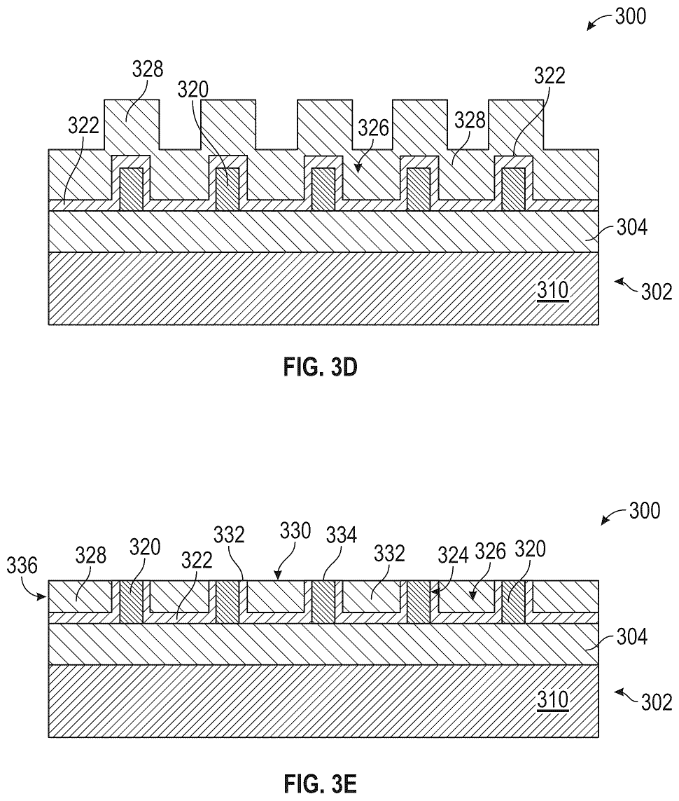

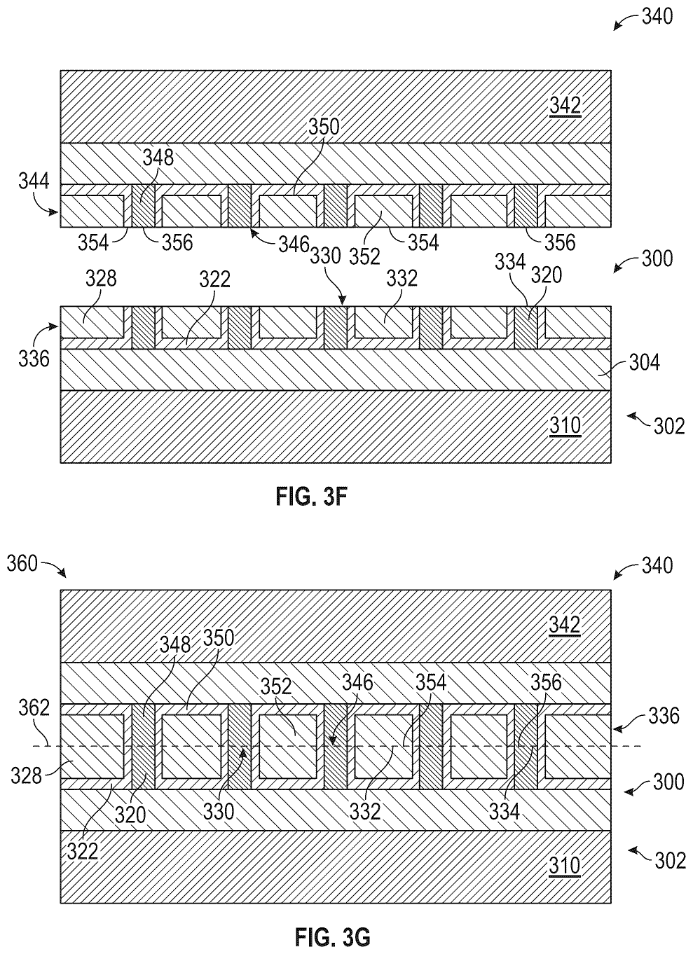

FIG. 2 is a flowchart illustrating a process 200 for forming a microelectronic element that includes forming a bonding layer on a substrate and then hybrid bonding a second element to the bonding layer. FIGS. 3A-3G are schematic side sectional views of microelectronic elements at various blocks of the process 200 shown in FIG. 2.

As shown in FIG. 3A, at block 202, a substrate 302 for an element 300 is provided. The substrate 302 may be similar or identical to the first element 102 discussed above in many respects. Accordingly, numerals used to identify features of the element 102 are incremented by 200 to identify similar or identical features of the substrate 302. For example, as shown in FIG. 3, the substrate 302 comprises a base substrate portion 310 having a front side 314 and an opposing back side 316. The base substrate portion 310, front side 314, and back side 316 can be similar or identical to base substrate portion 110a, 110b, front sides 114a, 114b, and back sides 116a, 116b. The substrate 302 can include any one or a combination of the features of the element 102.

In some embodiments, the substrate 302 comprises conductive features (e.g., active devices and/or circuitry, not shown) that can be patterned and/or otherwise disposed in or on the substrate 302. In some embodiments, the substrate 302 comprises a metallization layer 304 having a surface 318 that includes a field dielectric and conductive features embedded in the field dielectric. In these embodiments, the conductive features can be disposed at or near the front side 314 and/or at or near back side 316 and, in some embodiments, can be exposed at the surface 318. In other embodiments, however, the substrate 302 may not include active circuitry, but may instead be a dummy substrate, a passive interposer, a passive optical element (e.g., glass substrates, gratings, lenses), a temporary carrier, etc. In some embodiments, the substrate 302 comprises an optoelectronic single crystal material, including a perovskite material (e.g., LiTaO₃ or LiNbO₃), which are useful for optical piezoelectric or pyroelectric applications. In other embodiments, the substrate 302 comprises a more conventional substrate material, such as silicon (Si), quartz, fused silica glass, sapphire, glass, or a single crystal compound semiconductor material (e.g., III-V materials, such as GaAs or GaN). In general, the substrate 302 can comprise a semiconductor substrate, a glass substrate, an organic substrate, or a ceramic substrate.

As shown in FIG. 3B, at block 204, patterned metal features 320 are formed on the substrate 302 over the surface 318. The metal features 320 comprise a conductive metal (e.g., copper, nickel, gold, and/or aluminum) and can include vertical features (e.g., vias) and/or horizontal features (e.g., traces or routing lines) that extend laterally along the surface 318. In some embodiments, the metal features 320 comprise copper. The metal features 320 include sidewalls 324 that may be vertical or may be sloped. In embodiments where the metallization layer 304 includes conductive features exposed at the surface 318, at least some of the metal features 320 can be formed on and electrically connected to the exposed conductive features. In the illustrated embodiment, the metal features 320 are formed on the front side 314 of the substrate 302. In other embodiments, the metal features 320 are formed on the back side 316.

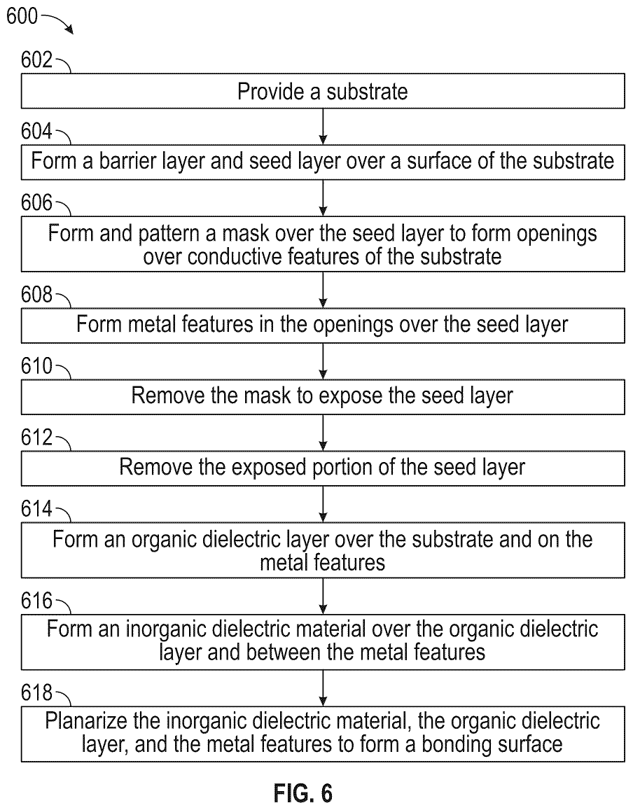

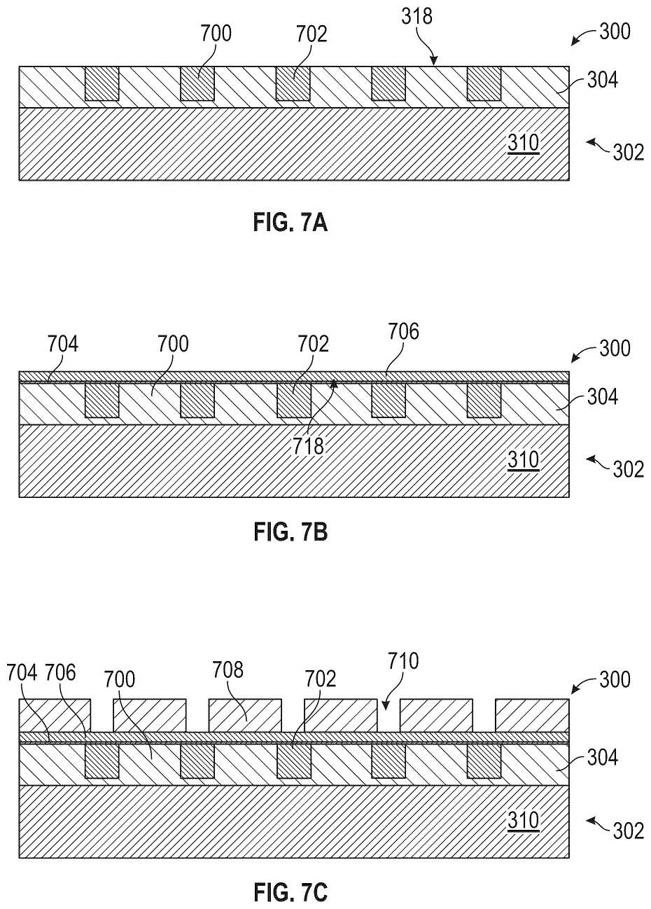

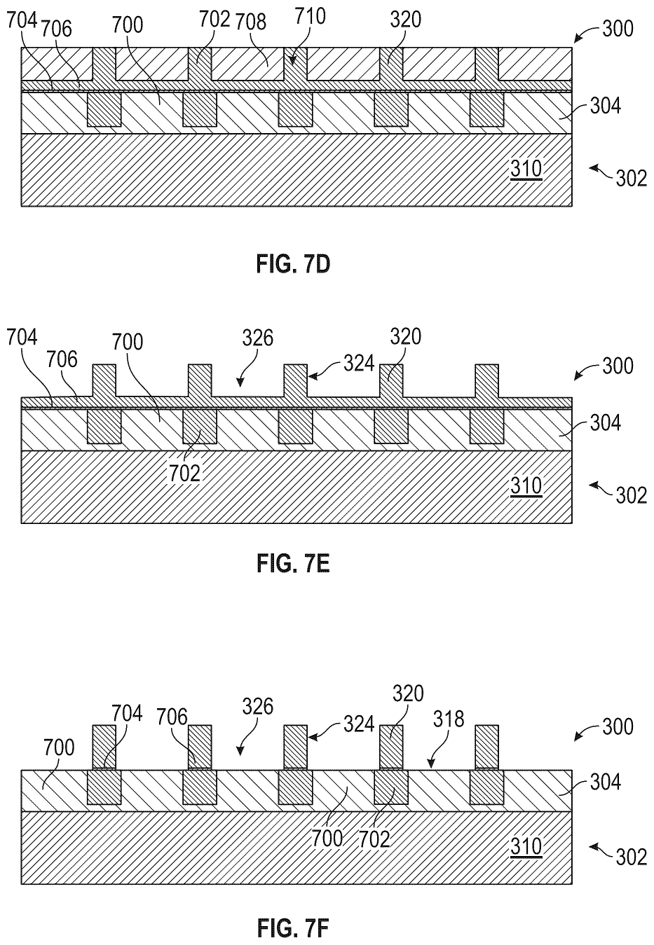

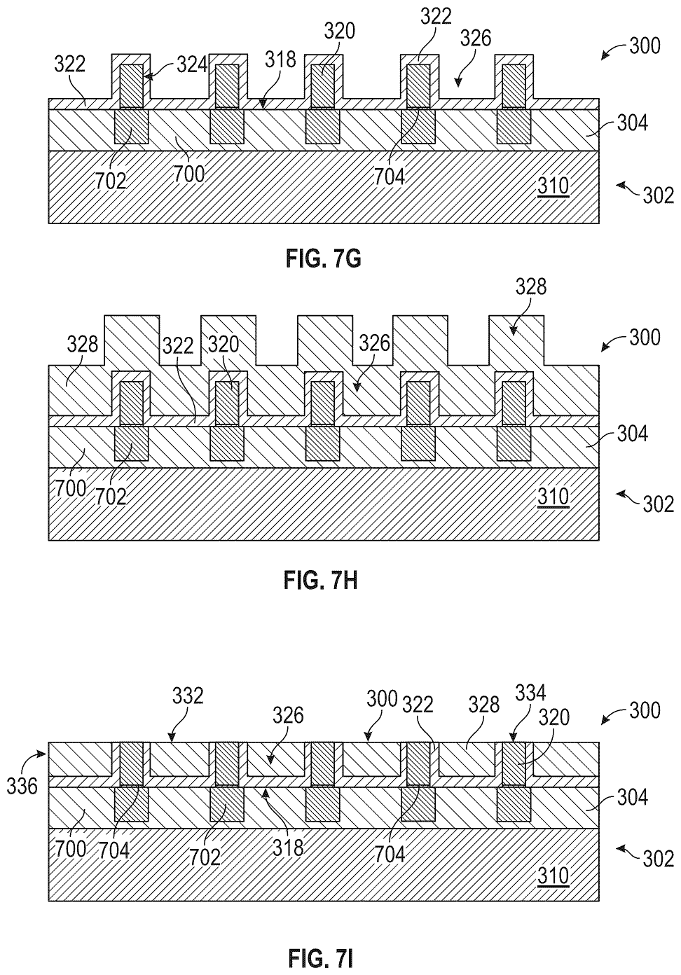

The metal features 320 can be formed using any suitable process. For example, in some embodiments, such as the embodiment of FIGS. 6-7I described below, the metal features 320 are formed by depositing a barrier layer and seed layer over the substrate 302, forming a mask over the seed layer, patterning the mask to form openings in the mask and expose the seed layer, depositing the conductive metal into the openings over the seed layer, and then removing the mask to expose the seed layer. The seed layer and barrier layer can then be removed. In other embodiments, a metal may be blanket deposited, patterned, and etched. In some embodiments, after forming the metal features 320, a liner can be formed on the metal features 320. For example, in some embodiments, a liner comprising silicon nitride can be deposited on at least the sidewalls 324 of the metal features 320.

As shown in FIG. 3C, at block 206, an organic dielectric layer 322 is formed over the substrate 302 and the metal features 320. The organic dielectric layer 322 includes vertical portions 322 formed over the sidewalls 324 of the metal features 320 and horizontal portions that at least partially cover the substrate 302. The presence of the organic dielectric layer 322 on the sidewalls 324 of the metal features 320 allows for a lower annealing temperature to be used in a subsequent annealing step as part of hybrid bonding because, as described in greater detail elsewhere in the specification, the expansion of the metal that forms the metal features 320 (e.g., copper metal) during the annealing process is less constrained by the organic dielectric layer 322. In some embodiments, the organic dielectric layer 322 is formed over the metal features 320 such that it directly contacts the metal features 320. In embodiments where a liner is formed on the metal features 320, however, the organic dielectric layer 322 can be formed over the metal features 320 such that it is formed on the liner.

The organic dielectric layer 322 is formed over the sidewalls 324 of the metal features 320 and in gaps 326 between adjacent metal features 320 but does not completely fill the gaps 326. Accordingly, the horizontal portions of the organic dielectric layer 322 has a thickness T that is less than the height H of the metal features 320. For example, in some embodiments, the thickness Tis at least 1 μm less than the height H. Accordingly, in some embodiments, a top surface of the metal features 320 is at least 1 μm higher than a top surface of the horizontal portions of the organic dielectric layer 322. In some embodiments, the thickness T of the organic dielectric layer 322 is between about 100 nm and about 3 μm. For example, in some embodiments, the thickness Tis between 100 nm and 500 nm, between 500 nm and 1000 nm, between 100 nm and 1000 nm, between 1000 nm and 3 μm, between 500 nm and 3 μm, or a value in a range defined by any of the foregoing thickness values. In some embodiments, the organic dielectric layer 322 is conformal. In some embodiments, the thickness T can vary across the organic dielectric layer 322. For example, in some embodiments the portions of the organic dielectric layer 322 formed on the metallization layer 304 can be thicker than the portion of the organic dielectric layer 322 formed on the metal features 320.

The organic dielectric layer 322 comprises a polymer material such as polyimide, polyamide, benzocyclobutene (BCB), polytetrafluoroethylene (PTFE), or mixtures of such materials. In some embodiments, the polymer material comprises a low-K organic dielectric material. In general, the organic dielectric layer 322 can comprise any polymer material that can be used to form a redistribution layer (RDL). In some embodiments, the organic dielectric layer 322 more than one type of polymer material.

In some embodiments, the organic dielectric layer 322 is formed by applying the organic dielectric material to the substrate 302 and metal features 320 using a conformal process. In some embodiments, the organic dielectric layer 322 is formed using a spin-on process. In other embodiments, the organic dielectric layer 322 is formed by a vapor deposition process. In some embodiments, after applying the organic dielectric material to the substrate 302 and the metal features 320, the organic dielectric material can be cured to form the organic dielectric layer 322. In some embodiments, the organic dielectric material is cured using heat, plasma, and/or light and the organic dielectric material is fully cured (e.g., hard cured) before any subsequent processes are performed. In other embodiments, the organic dielectric material is partially cured prior to additional processing. Whether any curing process is employed, and what process to use, depends the organic dielectric material that is used to form the organic dielectric layer 322. In some embodiments, the sidewalls 324 of the metal features 320 are defined by the main conductor (e.g., copper) that carries the majority of the current in operation, such that there is no intervening adhesion/barrier liner between the main conductor and the organic dielectric layer 322.

As shown in FIG. 3D, at block 208, an inorganic dielectric layer 328 is formed over the organic dielectric layer 322. The inorganic dielectric layer 328 is formed in the remaining portion of the gaps 326 between the adjacent metal features 320 and, in combination with the organic dielectric layer 322, can completely fill the gaps 326. The inorganic dielectric layer 328 can be formed directly on the organic dielectric layer 322 and therefore does not directly contact the metal features 320. In some embodiments, the inorganic dielectric layer 328 comprises an inorganic dielectric material. In some embodiments, the inorganic dielectric layer 328 comprises silicon oxide. In other embodiments, however, the inorganic dielectric layer 328 comprises a different inorganic dielectric material, such as silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In general, the inorganic dielectric layer 328 can be formed from any dielectric material capable of forming a dielectric-to-dielectric direct bond with another dielectric material, as described herein. The inorganic dielectric layer 328 can also comprise multiple different materials, either as mixtures or as multiple sub-layers.

As shown in FIG. 3E, at block 210, the inorganic dielectric layer 328, the organic dielectric layer 322, and the metal features 320 are planarized to form a bonding surface 330. In some embodiments, planarizing the inorganic dielectric layer 328 and the organic dielectric layer 322 comprises removing the portions of the inorganic dielectric layer 328 and the organic dielectric layer 322 formed above the metal features 320 to expose the metal features 320. In some embodiments, planarizing the inorganic dielectric layer 328 also comprises removing some of the portion of the inorganic dielectric layer 328 and the organic dielectric layer 322 formed in the gaps 326. In some embodiments, planarizing the metal features 320 comprises stopping on the metal features, and can include removing at least some of the metal (e.g., copper) of the metal features 320.

The inorganic dielectric layer 328, the organic dielectric layer 322, and the metal features 320 can be planarized using any suitable planarization process. For example, in some embodiments, the planarization process comprises a CMP process that involves using a polishing pad and a slurry to polish the inorganic dielectric layer 328, the organic dielectric layer 322, and the metal features 320 to form the bonding surface 330. Additionally, unlike in conventional damascene processes where metal overburden from plating is to be removed, the CMP process need not remove significant amounts of metal during the planarization process and can be performed with a single polishing pad and a single slurry chemistry. Although no barrier is present in the illustrated embodiment, the slurry can be the same as those termed a “barrier slurry” in the industry, as it is tuned to remove oxides and metal (typically copper) at roughly the same rates, or to slightly recess the metal. After performing the CMP process using the single polishing pad and the single slurry chemistry, the top surface of the metal features 320 can be recessed below the top surface of the inorganic dielectric layer 328.

The inorganic dielectric layer 328, the organic dielectric layer 322, and the metal features 320 together form a bonding layer 336 of the element 300. The bonding layer 336 includes the bonding surface 330 and is formed on front side 310 of the metallization layer 304. However, the bonding layer 336 does not include a barrier layer between the sidewalls 324 of the metal features 320 and the organic dielectric layer 322. In some embodiments, the sidewalls 324 of the metal features 320 are defined by the main conductor (e.g., copper) of the metal features 320 that carry the majority of the current, and the sidewalls 324 are in direct contact with the organic dielectric layer 322. Accordingly, in some embodiments, the organic dielectric layer 322 can directly contacts the sidewalls 324 of the metal features 320. In embodiments where a liner is formed over the metal features 320 before the organic dielectric layer 322 is formed, the liner can directly contact the sidewalls 324 and the organic dielectric layer 322 can contact the liner.

The height H of the metal features 320 can affect the hybrid bonding performance of the bonding layer 336. For example, greater height H can provide more metal for expansion during anneal, such that for a given gap to bridge, the anneal temperature can be lowered. However, changing the height H of the metal features 320 increase the internal stresses within the bonding layer 336. Forming the bonding layer 336 such that it includes both the organic dielectric layer 322 and the inorganic dielectric layer 328 allows for greater control in the height of the metal features 320 because the relative thicknesses of the organic dielectric layer 322 and the inorganic dielectric layer 328 can be varied to alleviate stress and allow greater variation in the height H of the metal features 320 (which can also represent the thickness of the bonding layer 336).

At block 212, the bonding surface 330 can be prepared for hybrid bonding. In some embodiments, preparing the bonding surface 330 for hybrid bonding comprises polishing the bonding surface 330 to a high degree, as described above, as part of or after the planarization process at block 210. In some embodiments, preparing the bonding surface 330 additionally comprises activating and/or terminating the bonding surface 330. In some embodiments, activating the bonding surface 330 comprises plasma activating the bonding surface 330 by exposing the bonding surface 330 to one or more plasmas, such as a nitrogen plasma and/or an oxygen plasma, or by slight etching. In some embodiments, the activation or other process can result in terminating species, such as nitrogen, that can increase bonding strength. In some embodiments, activating the bonding surface 330 comprises chemically activating the bonding surface. In some embodiments, preparing the bonding surface 330 for hybrid bonding comprises rinsing the bonding surface 330 to remove any particulate matter on the bonding surface 330, and then drying the bonding surface 330. Activation can sometimes be omitted, particularly if the other surface to be hybrid bonded to the bonding surface 330 is activated. Termination can also be provided separately from or without plasma activation, such as by ammonium dip.

After preparing the bonding surface 330 for hybrid bonding, the bonding surface 330 comprises a hybrid bonding surface that includes a dielectric field region 332 and contact regions 334, where the dielectric field region 332 includes both inorganic portions formed by the inorganic dielectric layer 328 and organic portions formed by exposed edges of the organic dielectric layer 322, and where the contact regions 334 are formed from the exposed surfaces of the metal features 320. The thickness of the inorganic dielectric layer 328 over horizontal portions of the organic dielectric layer 322 is at least about 1 μm, and in some embodiments can be between about 1 μm and 2 μm. In some embodiments, the inorganic dielectric layer 328 can represent at least 50 area % of the bonding surface 330. For example in some embodiments, the inorganic dielectric layer 328 can represent between 50% and 99% of the surface area of the bonding surface 330, between the 60% and 99% of the surface area of the bonding surface 330, between the 60% and 80% of the surface area of the bonding surface 330, between the 80% and 99% of the surface area of the bonding surface 330, between the 90% and 99% of the surface area of the bonding surface 330, or a value in a range defined by any of these values. In some embodiments, the amount of the surface area of the bonding surface 330 that the inorganic dielectric layer 328 makes up can depend upon the density and pitch of the metal features 320. In general, the greater the inorganic proportion of the dielectric field region, the stronger the direct bond. In some embodiments, after planarizing the inorganic dielectric layer 328, the organic dielectric layer 322, and the metal features 320, the contact regions 334 are flush with the dielectric field region 332. In other embodiments, however, the contact regions 334 are recessed below the dielectric field region 332. Desirably, the recesses are relatively uniform across the element 300. In still other embodiments, the contact regions 334 protrude above the dielectric field region 332. Desirably, the protrusions are relatively uniform across the element 300.

As shown in FIG. 3F, at block 214, a second element 340 is provided. The second element 340 has a bonding layer structure that can be generally similar to the structure of the element 300 (which can also be referred to as first element 300). The illustrated second element 340 includes a base substrate portion 342, a bonding layer 344, and a bonding surface 346. The bonding layer 344 has metal features 348, an organic dielectric layer 350 formed directly on the sidewalls of the metal features 348, and an inorganic dielectric layer 352 formed over the organic dielectric layer 350. The bonding surface 346 includes a dielectric field region 354 and contact regions 356, where the dielectric field region 354 include organic portions formed by exposed edges of the organic dielectric layer 350 and inorganic portions formed by the inorganic dielectric layer 352, and where the contact regions 356 are formed from the exposed surfaces of the metal features 348. In some embodiments, the bonding surface 346 comprises a hybrid bonding surface that has been polished, activated, and/or terminated. In some embodiments, the bonding layer 344 is formed using a process that is generally similar to the process used to form the bonding layer 336.

As shown in FIG. 3G, at block 216, the second element 340 is hybrid bonded to the bonding layer 336 of the element 300 to form a bonded structure 360. The second element 340 can be hybrid bonded to the bonding layer 336 of the element 300 by contacting the second bonding surface 346 to the bonding surface 330 at a bond interface 362 so that the dielectric field region 332 of the first element 300 and the dielectric field region 354 of the second element 340 contact each other, which can cause chemical bonds (e.g., covalent bonds) to spontaneously form between the dielectric material of the dielectric field region 332 (particularly the inorganic portions of the dielectric field region 332) and the dielectric material of the dielectric field region 354 (particularly the inorganic portions of the dielectric field region 354), even at room temperature and without external pressure beyond initiating contact. Additionally, hybrid bonding the second element 340 to the bonding layer 336 of the element 300 can be performed without the use of an intervening adhesive between the bonding surface 330 and the bonding surface 346.

In some embodiments, hybrid bonding the element 300 to the second element can include annealing bonded structure 360 to cause the metal features 320, 348 to expand so that the contact regions 334 contact the contact regions 356. In some embodiments, annealing element 300 and the second element causes the metal features 320 and/or the metal features 348 to expand and contact each other at the bond interface 362, resulting in the materials of the contact regions 334 inter-diffusing with the materials of the opposing conductive features. In some embodiments, annealing the bonded structure 360 can also increase the strength of the chemical bonds between the dielectric field regions 332, 354.

The presence of the organic dielectric layer 322 directly on the sidewalls 324 of the metal features 320 allows for a lower annealing temperature (e.g., an annealing temperature less than 250° C.) to be used in a subsequent annealing step as part of hybrid bonding because the expansion of the metal that forms the metal features 320 (e.g., copper metal) during the annealing process is less constrained by the organic dielectric layer 322. This is because the polymer material that forms the organic dielectric layer 322 is more flexible than the materials that surround the metal features in conventional damascene structures (e.g., inorganic dielectric materials and/or adhesion/barrier materials). When the metal features 320 expand during the annealing process, the flexible organic dielectric layer 322 can flex and stretch with the metal features 320 without constraining (or without substantially constraining) the expanding metal features 320. Accordingly, forming the organic dielectric layer 322 over the metal features 320 such that it directly contacts the sidewalls 324 of the metal features 320 and is positioned between a field dielectric 328 and the metal features 320 can allow for low-temperature annealing for subsequent hybrid bonding, which means that any performance degradation of the element and/or bonded structure due to exceeding the thermal budget of the element and/or bonded structure can be reduced or even avoided. For example, in some embodiments, annealing the element 300 and the second element 340 can be performed at a temperature of 250° C. or less, due at least in part to presence of the organic dielectric layer 322 on the sidewalls 324. In other embodiments, however, the element 300 and the second element 340 can be annealed at a different temperature. For example, in some embodiments, hybrid bonding the element 300 to the second element 340 comprises annealing the first element 300 and the second element 340 at a temperature of 300° C. or less, 250° C. or less, 200° C. or less, 150° C. or less, 100° C. or less, a temperature between 50° C. and 300° C., a temperature between 100° C., and 250° C., a temperature between 150° C. and 200° C., or a temperature in a range defined between any of the foregoing temperature values.

In some embodiments, the first and second elements 300, 340 are hybrid bonded together at the bond interface 362 such that the contact regions 334 are aligned with the corresponding contact regions 356 and the dielectric field region 332 is aligned with the dielectric field region 354. In these embodiments, the contact regions 334 do not overlap with or contact the dielectric field region 354, the organic portions of the dielectric field region 332 overlap with organic portions of the dielectric field region 354, and the inorganic portions of the dielectric field region 332 overlap with and are directly bonded to the inorganic portions of the dielectric field region 354. In other embodiments, the first and second elements 300, 340 can be hybrid bonded together such that one or more of the contact regions 334 can be slightly misaligned with the corresponding contact region(s) 356 but still form functional bonds. For example, in some embodiments, a portion of one or more of the contact regions 334 overlaps with and contacts a corresponding one of the contact regions 356 while another portion of the contact region(s) overlap with and contacts a portion of the dielectric field region 354 (e.g., an organic portion of the dielectric field region 354). In such embodiments, of course, the dielectric field region 332 is also slightly misaligned with the dielectric field region 354. For example, in some embodiments, an organic portion of the dielectric field region 332 overlaps with an inorganic portion of the dielectric field region 354.

After hybrid bonding the element 300 to the second element 340 to form the bonded structure 360, the bonded structure 360 can undergo additional processing. For example, in some embodiments, the bonded structure 360 can be singulated to form one or more singulated bonded structures and/or can be bonded to one or more other elements (e.g., dies, substrates, wafers, etc.). In some embodiments, the additional processing can include thinning the bonded structure 360 (either before or after being singulated and/or bonded to another element or after). For example, in some embodiments, the backsides of one or both of element 300 and the second element 340 can be thinned. In some embodiments, after thinning, the backsides of one or both of the elements can be etched to reveal TSVs or other metallization structures within the elements 300, 340. In some embodiments, the additional processing can include processing the backside of one or both of the elements 300, 340 to form one or more additional bonding surfaces. In some embodiments, a conductive barrier layer can be formed between one or more of the exposed metallization structures and the deposited conductive layer. In some embodiments, one or more other elements (e.g., dies, substrates, wafers, etc.) can be bonded to the backside (e.g., to the bonding surface or the conductive layer) of one or both of the elements 300, 340.

In the embodiments shown in FIGS. 3F and 3G, the second element 340 has a structure that is generally similar to the element 300. In other embodiments, however, the element 300 can be hybrid bonded to a second element having a different structure than the element 300.

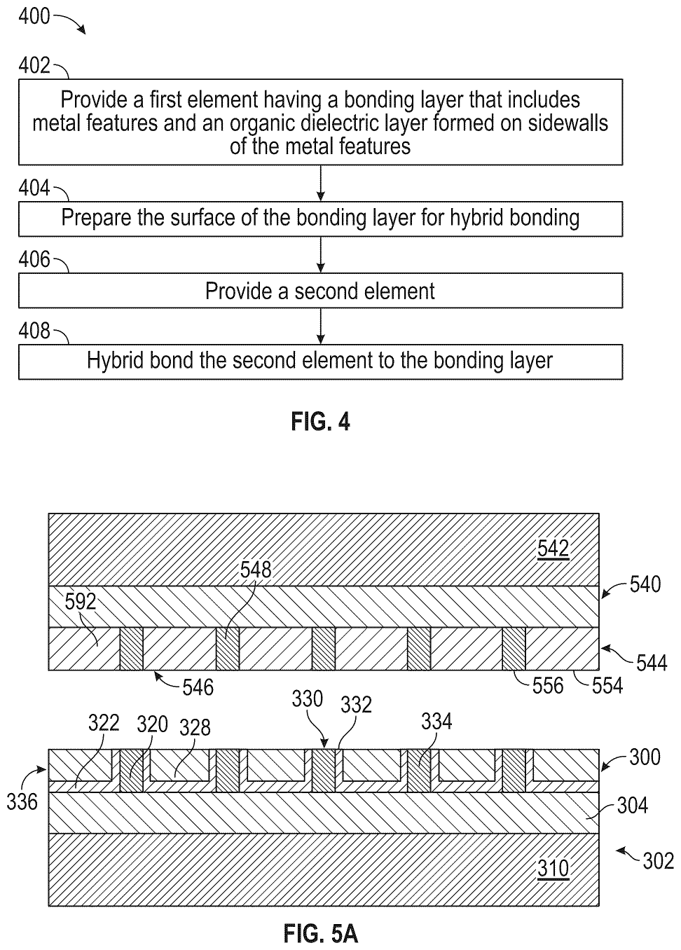

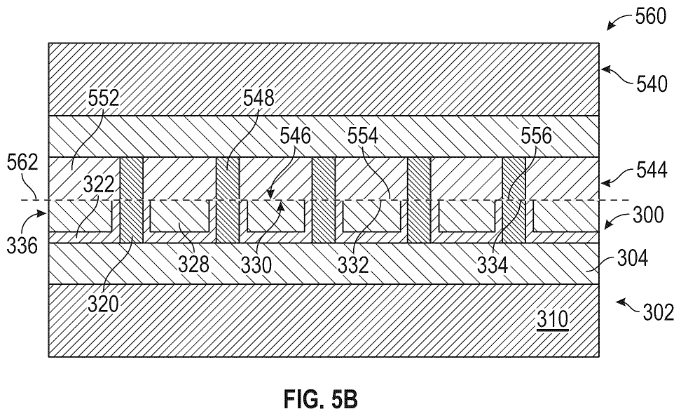

FIG. 4 is a flowchart illustrating a process 400 for forming a bonded structure that includes hybrid bonding element 300 to a second element having a different structure than the element 300. FIGS. 5A and 5B are schematic side sectional views of a microelectronic elements at various blocks of the process 400 shown in FIG. 4.

At block 402, a first element 300 having the bonding layer 336 is provided. As described above in connection with FIGS. 2-3E, the bonding layer 336 is formed by forming the metal features 320 over the substrate 302, and subsequently forming the organic dielectric layer 322 over the substrate 302 and the metal features 320 such that the organic dielectric layer 322 is formed directly on the sidewalls 324 of the metal features 320. The inorganic dielectric layer 328 is then formed on the organic dielectric layer 322 and then the inorganic dielectric layer 328, the organic dielectric layer 322, and the metal features 320 are planarized to form the bonding surface 330 of the bonding layer 336.

At block 404, the bonding surface 330 is prepared for hybrid bonding.

As shown in FIG. 5A, at block 406, a second element 540 is provided. The second element 540 includes a base substrate potion 542 and a bonding layer 544 having a bonding surface 546. The bonding layer 544 has metal features 548 and an inorganic dielectric layer 552 formed in the gaps between adjacent metal features 548. The bonding surface 546 includes a dielectric field region 554 and contact regions 556, where the dielectric field region 554 comprises an upper surface of the inorganic dielectric layer 552 and where the contact regions 556 are formed from the exposed surfaces of the metal features 548. In some embodiments, the bonding surface 546 comprises a hybrid bonding surface that has been polished, activated, and or terminated.

In some embodiments, the bonding layer 544 is formed on the base substrate portion 542 using a process that is generally similar to the process used to form the bonding layer 336 on the base substrate portion 310 (e.g., a build-up process whereby the metal features 548 are formed on the base substrate portion 542 before the inorganic dielectric layer 552 is formed over the metal features 548). In other embodiments, however, the bonding layer 544 is formed using a different process. For example, in some embodiments, the bonding layer 544 is formed using a damascene process whereby the inorganic dielectric layer 552 is formed over the base substrate portion 542 and then patterned to form openings in the inorganic dielectric layer 552 before metal (e.g., copper metal) is deposited into the openings to form the metal features 548. In these embodiments, the metal features 548 can include an adhesion/barrier layer on their sidewalls between the main conductor (e.g., copper), which carries the majority of the current, and the inorganic dielectric layer 552.

As shown in FIG. 5B, at block 408, the second element 540 is hybrid bonded to the bonding layer 336 of the element 300 to form a bonded structure 560. The second element 540 can be hybrid bonded to the bonding layer 336 of the element 300 by contacting the second bonding surface 546 to the bonding surface 330 at the bond interface 562 so that the dielectric field region 332 contacts the dielectric field region 354, which can cause chemical bonds to spontaneously form between dielectric material of the dielectric field region 332 (particularly the inorganic portions of the dielectric field region 332) and dielectric material of the dielectric field region 554 (particularly the inorganic portions of the dielectric field region 354), even at room temperature and without external pressure beyond initiating contact. Additionally, hybrid bonding the second element 540 to the bonding layer 336 of the element 340 is performed without the use of an intervening adhesive between the bonding surface 330 and the second bonding surface 346.

Before annealing the first and second elements 300, 540, the contact regions 334 can be recessed below the dielectric field region 332. In some embodiments, the contact regions 556 are also recessed below the dielectric region 554. With this arrangement, immediately after contacting the second bonding surface 546 to the bonding surface 330, the surface of each of the contact regions 334 can be spaced apart from the surface of an opposing contact region 556 by a total gap. To close this total gap and complete direct bonding of the metal features 320, 548, in some embodiments, hybrid bonding the second element 340 to the bonding layer 336 of the element 300 can include annealing the bonded structure 560 to cause the metal features 320 and/or the metal features 548 to expand and contact each other. However, the amount that the metal features 320, 548 expand during the annealing process can depend on various factors, including the type of metal used to form the metal features 320, 548, the size and shape of the metal features 320, 548, the annealing temperature, and the structure of the bonding layers 336, 544.

As discussed above in connection with FIG. 3C, the presence of the organic dielectric layer 322 on the sidewalls 324 of the metal features 320 allows for low-temperature annealing because the metal features 320 are less constrained by the flexible polymer material that forms the organic dielectric layer 322. In some embodiments, the organic dielectric layer 322 is also in direct contact with the main conductor of the metal features 320. In contrast, the bonding layer 544 does not include an organic dielectric material on the sidewalls of the metal features 548 typically the metal features 548 also include an adhesion/barrier layer, which can restrict or restrain the expansion of the metal features 548 during annealing. Accordingly, during the annealing process, the metal features 320 can expand more than the metal features 548, which allows for the bonded structure 560 to be annealed at a lower temperature than in conventional hybrid bonding processes. This is because the metal features 320 can expand more than a conventional metal feature (e.g., a metal feature formed using a conventional damascene process) when annealed at a lower annealing temperature (e.g., an annealing temperature less than 250° C.), which means that the metal features 320 can expand and close the total gap between the metal features 320, 548 at the lower annealing temperature, even if the metal features 548 do not expand as much when heated to the lower annealing temperature. This arrangement allows for the second element 540 to be formed from temperature sensitive materials that do not have the thermal budget to be reliably annealed at conventional annealing temperatures, or to use more of the available thermal budget for other processing rather than for annealing.

After hybrid bonding the element 300 to the second element 540 to form the bonded structure 560, the bonded structure 560 can undergo additional processing, such as singulation, thinning, etching, backside processing, the formation of one or more additional layers on the backside(s) of one or both of the elements 300, 540, and/or bonding one or more other elements to one or both of the elements 300, 540.

FIG. 6 is a flowchart illustrating more detailed process 600 for forming the bonding layer 336 on the substrate 302 of the element 300. FIGS. 7A-7H are schematic side sectional views of the element 300 at various blocks of the process 600 shown in FIG. 6.

As shown in FIG. 7A, at block 602, substrate 302 of element 300 is provided. The metallization layer 304 of the substrate 302 includes a field dielectric 700 and conductive features 702 embedded in the field dielectric and exposed at the surface 318.

As shown in FIG. 7B, at block 604, a barrier layer 704 and a seed layer 706 are formed over the surface of the metallization layer 304 of the substrate 302.

In some embodiments, the barrier layer 704 comprises a conductive barrier material, such as such as a barrier metal, barrier alloy, or barrier metal nitride. For example, in some embodiments, the barrier layer 704 comprises one or more of titanium metal, titanium nitride, tantalum metal, tantalum nitride, ruthenium, tungsten, titanium-tungsten alloy, etc. The barrier layer 704 is formed by depositing the conductive barrier material over the surface 318 such that the conductive barrier material covers the surface 318. In some embodiments, including the illustrated embodiment, the barrier layer 704 completely covers the surface 318. In other embodiments, the barrier layer 704 only partially covers the surface 318. For example, in some embodiments, the barrier layer 704 covers the field dielectric 700 without covering one or more of the conductive features 702.

The seed layer 706 is formed over the barrier layer 704. In some embodiments, the seed layer 706 comprises a conductive metal. For example, in some embodiments, the seed layer 706 comprises copper, aluminum, nickel, and/or gold. The seed layer 706 is formed by blanket depositing the conductive metal over the barrier layer 704. In some embodiments, including the illustrated embodiment, the seed layer 706 completely covers the barrier layer 704. In other embodiments, however, the seed layer 706 only partially covers the barrier layer 704. For example, in some embodiments, the seed layer 706 is formed over the conductive features 702 without being formed over at least a portion of the field dielectric 700.

As shown in FIG. 7C, at block 606, a mask 708 is formed over the seed layer 706 and patterned to form openings 710 in the mask 708. The mask 708 can be formed from any suitable material, such as resist, and can be patterned using any suitable patterning technique. For example, in some embodiments, the mask 708 can be patterned by selectively irradiating and developing a photoresist layer, or a patterned resist can have its pattern extended down into a hard mask material. The openings 710 can extend through the mask 708 and can be formed over the conductive features 702 such that the portions of the seed layer 706 formed over the conductive features 702 are exposed through the openings 710. The size and shape of the individual openings 710 correspond to the planned size and shape of the corresponding metal features (e.g., metal features 320) that are to be formed in each of the openings 710. The openings 710 can have a straight profile, a V-shaped profile, or any other suitable profile and, in some embodiments, the profile can depend on the process used to pattern the openings 710 in the mask 708 and/or the material from which the mask 708 is formed.

As shown in FIG. 7D, at block 608, metal features 320 are formed in the openings 710 such that they directly contact the seed layer 706. In some embodiments, the metal features 320 are formed by plating (e.g., electroplating) a conductive metal (e.g., copper, aluminum, gold, nickel) into the openings 710. In some embodiments, the metal features 320 completely fill the openings 710 such that an upper surface of the metal features 320 is generally coplanar with the top surface of the mask 708. In other embodiments, however, the metal features 320 do not completely fill the openings 710 and the upper surface of the metal features 320 is recessed below the top surface of the mask 708. In some embodiments, the skilled artisan can determine that the metal features 320 were formed by electroplating through a resist mask, as opposed to a damascene structure filling an opening in an inorganic insulator that remains in place.

As shown in FIG. 7E, at block 610, the mask 708 is selectively removed to expose one more portions of the seed layer 706 and to expose the sidewalls 324 of the metal features 320. After removing the mask 708, the metal features 320 can be separated from each other by gaps 326, which can extend between adjacent metal features 320. The mask 708 can be removed by any suitable process, such as resist stripping if the mask comprises resist.

As shown in FIG. 7F, at block 612, the exposed portions of the seed layer 706 and the underlying barrier layer 704 are removed to expose portions of the metallization layer 304. In some embodiments, exposing the portions of the metallization layer 304 comprises a portion of the field dielectric 700. In some embodiments, removing the exposed portion of the seed layer 706 and the underlying barrier layer 704 to expose portions of the seed layer 706 comprises removing the portions of the seed layer 706 that are not covered by the metal features 320. In some embodiments, removing the portions of the seed layer 706 and the underlying barrier layer 704 comprises etching away the portions of the seed layer 706 and the underlying barrier layer 704 by exposing the portions the seed layer 706 and the underlying barrier layer 704 to one or more etchants. In some embodiments, etching away the exposed portions of the seed layer 706 and the underlying barrier layer 704 comprises wet etching (e.g., blanket wet etching) or dry etching the exposed portions of the seed layer 706 and the underlying barrier layer 704. In some embodiments, exposing the exposed portions of the seed layer 706 and the underlying barrier layer 704 to the etchant results in a portion of the metal features 320 being exposed to the etchant. In these embodiments, the etchant can also remove some of the metal from the metal features 320 during the etching process. Because the seed layer 706 and the barrier layer 704 are both thin relative to the metal features 320, the removal of the layers 704, 706 does not significantly damage the metal features 320.

In some embodiments, the exposed portions of the seed layer 706 and the underlying barrier layer 704 are removed in a single removal process. For example, in embodiments where the exposed portions of the seed layer 706 and the underlying barrier layer 704 are removed by exposing the exposed portions of the seed layer 706 and the underlying barrier layer 704 to etchant, the etchant can be capable of etching both the metal that forms the seed layer 706 and the conductive barrier material. In other embodiments, however, the exposed portions of the seed layer 706 and the underlying barrier layer 704 are removed in multiple processes. For example, a first etchant that is configured to selectively etch metal without etching the conductive barrier material can be used to remove the exposed portions of the seed layer 706 in a first process and then a second etchant capable of etching the conductive barrier material can be used to remove the underlying barrier layer 704. In some embodiments, at least some of the field dielectric 700 of the underlying metallization layer 304 can also be removed during the removal of the exposed portions of the seed layer 706 and the underlying barrier layer 704. In some embodiments, at least the etch employed to remove the barrier layer 704 is selective relative to the underlying field dielectric 700. In some embodiments, after forming the metal features 320 and removing the mask 708 and the exposed portions of the seed layer 706 and underlying barrier layer 704, a liner (e.g., a silicon nitride liner) can be formed on the metal features 320.

As shown in FIG. 7G, at block 614, the organic dielectric layer 322 is formed over the substrate 302 and the metal features 320 such that the organic dielectric layer 322 is formed on the sidewalls 324 of the metal features 320 and in the gaps 326 between adjacent metal features 320. In some embodiments, the organic dielectric layer 322 is formed over the metal features 320 such that it directly contacts the main conductor of the metal features 320, without intervening liners such as adhesion/barrier layers. In embodiments where a liner is formed on the metal features 320, however, the organic dielectric layer 322 is formed over the metal features 320 such that it is formed on the liner. In embodiments where a width of one or more of the metal features 320 is less than a width of the underlying conductive feature 702 on which the one or more metal features 320 is formed, the organic dielectric layer 322 can contact an exposed portion of the conductive feature(s) 702.

As shown in FIG. 7H, at block 616, the inorganic dielectric layer 328 is formed over the organic dielectric layer 322. The inorganic dielectric layer 328 is formed in the gaps 326 between the adjacent metal features 320 and, in combination with the organic dielectric layer 322, completely fills the gaps 326. The inorganic dielectric layer 328 can be formed directly on the organic dielectric layer 322 and therefore does not directly contact the metal features 320.

As shown in FIG. 7I, at block 618, the inorganic dielectric layer 328, the organic dielectric layer 322, and the metal features 320 are planarized to form the bonding surface 330. The planarized inorganic dielectric layer 328, organic dielectric layer 322, and metal features 320 form the bonding layer 336 and the bonding surface 330 therefore includes the metallic contact regions 334 of the metal features 320 and the dielectric field regions 332 of the organic dielectric layer 322 and the inorganic dielectric layer 328. After forming the bonding surface 330, the element 300 can undergo additional processing, such as bonding a second element (e.g., second elements 340, 540) to the bonding surface 330.

In the embodiments shown and described in FIGS. 2-71, the bonding layer is formed by a build-up process of forming metal features on the substrate by depositing metal onto the surface of the substrate and then forming the organic dielectric layer over the deposited metal features. In other embodiments, however, the bonding layer can be formed by revealing TSVs in the substrate and then depositing the organic dielectric layer over the revealed TSVs.

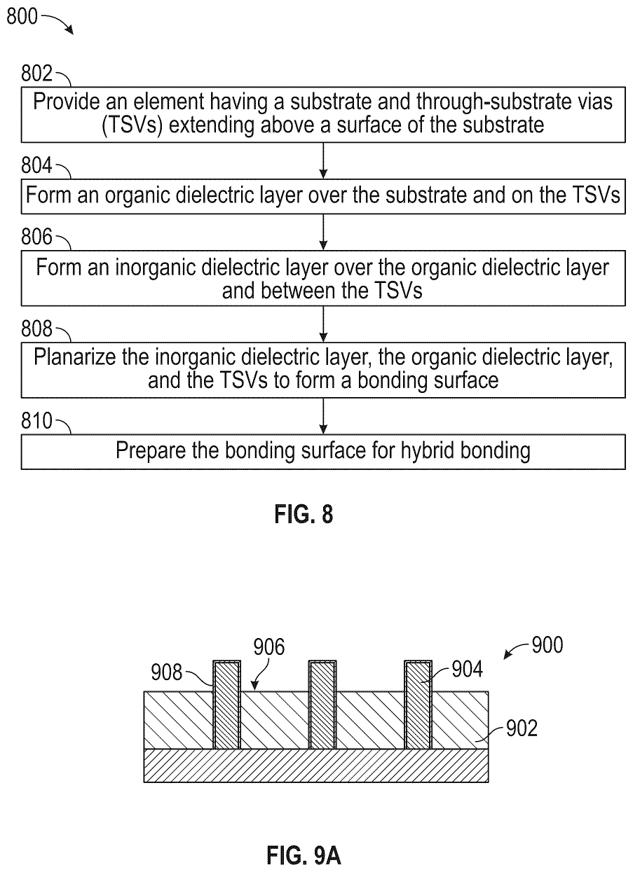

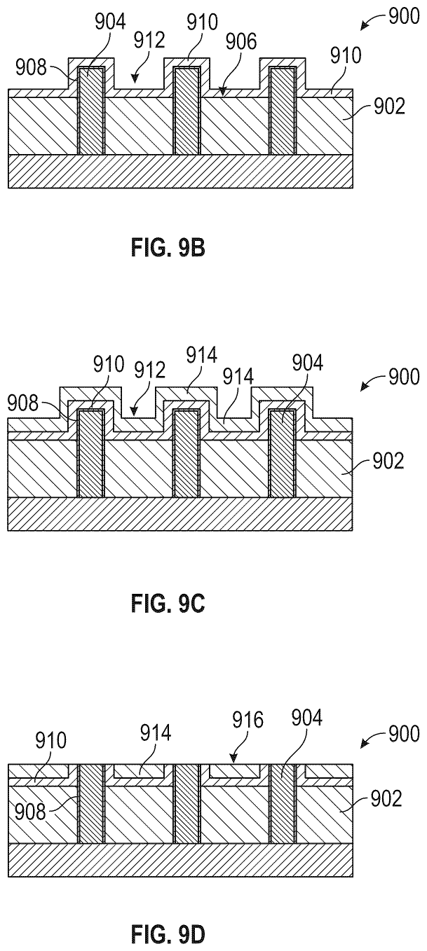

FIG. 8 is a flowchart illustrating a process 800 forming a bonding layer that includes revealed TSVs. FIGS. 9A-9F are side sectional views of microelectronic elements at various blocks of the process 800 shown in FIG. 8.

As shown in FIG. 9A, at block 802, an element 900 is provided. The element 900 comprises a substrate 902 and TSVs 904 that comprise a conductive metal (e.g., copper) as the main conductor, and that extend above a surface 906 of the substrate 902. The illustrated TSVs 904 include a TSV liner 908 over the main conductor, which can include an inorganic dielectric material and/or a conductive barrier layer. For example, in some embodiments, TSV liner 908 comprises Ti metal and/or TiN or Ta metal and/or TaN. The TSV liner 908 can also include an inorganic liner, such as silicon oxide, over a conductive barrier. The TSVs 904 can be formed using any suitable method, including via-first or via-middle techniques and the TSVs 904 can be revealed using any suitable TSV reveal process, including lapping, grinding, polishing, and/or selective semiconductor etch back, etc.

As shown in FIG. 9B, at block 804, an organic dielectric layer 910 is formed over the substrate 902 and the TSVs 904. The organic dielectric layer 910, which can be generally similar to organic dielectric layer 322, is formed conformally on the TSV liner 908 and over the surface 906 over the substrate 902 such that the organic dielectric layer 910 is formed in the gaps 912 between adjacent TSVs 904 but does not completely fill the gaps 912. Accordingly, a thickness of the organic dielectric layer 910 is less than the height of the TSVs 904 above the surface 906 by at least 1 μm. In some embodiments, the thickness of the organic dielectric layer 910 is between about 100 nm and about 3 μm. For example, in some embodiments, the thickness of the organic dielectric layer 910 is between 100 nm and 500 nm, between 500 nm and 1000 nm, between 100 nm and 1000 nm, between 1000 nm and 3 μm, between 500 nm and 3 μm, or a value in a range defined by any of the foregoing thickness values. The organic dielectric layer 910 can comprise an organic dielectric material, such as a low-K organic dielectric material or any polymer material that can be used to form a redistribution layer (RDL), such as the example materials described above with respect to FIG. 3C. The organic dielectric layer 910 can be formed using a conformal process to apply the organic dielectric material to the substrate and the TSVs and then curing the organic dielectric layer 910. The TSVs 904 extend into the substrate 902 such that a portion of the TSV is embedded below the surface 906. Accordingly, the organic dielectric layer 910 lines the exposed portions of the TSVs (e.g., the portions of the TSV 904 that extend over the surface 906) but does not line the portions of the TSVs embedded in the substrate 902 below the surface 906.

As shown in FIG. 9C, at block 806, an inorganic dielectric layer 914 is formed over the organic dielectric layer 910. The inorganic dielectric layer 914, which can be generally similar to inorganic dielectric layer 328 and can include one or more material layers, is formed in the gaps 912 between the adjacent TSVs 904 and, in combination with the organic dielectric layer 910, can completely fill the gaps 912. The inorganic dielectric layer 914 can be formed directly on the organic dielectric layer 910 and therefore does not directly contact the TSVs 904.

In the illustrated embodiment, the organic dielectric layer 910 is formed on the TSV liner 908 such that the organic dielectric layer 910 does not directly contact the metal that forms the TSVs 904. However, the presence of the organic dielectric layer 910 between the TSV liner 908 and the inorganic dielectric layer 914 can still allow for reduced annealing temperatures due to the increased flexibility of the organic dielectric material.

As shown in FIG. 9D, at block 808, the inorganic dielectric layer 914, the organic dielectric layer 910, and the TSVs 904 are planarized to form an upper surface 916, which can serve as a bonding surface. Planarizing the inorganic dielectric layer 914 and the organic dielectric layer 910 can comprise completely removing the portions of the inorganic dielectric layer 914 and the organic dielectric layer 910 formed above the TSVs 904 to expose the TSVs 904. In some embodiments, planarizing the inorganic dielectric layer 914 also comprises removing some of the portion of the inorganic dielectric layer 914 and the organic dielectric layer 910 formed in the gaps 912. In some embodiments, planarizing the TSVs 904 comprises removing at least some of the metal that forms the main conductor of the TSVs 904. The thickness of inorganic dielectric layer 914, over horizontal portions of the organic dielectric layer 910, is at least about 1 μm, and in some embodiments can be between about 1 μm and 2 μm. In some embodiments, the inorganic dielectric layer 914 can represent at least 50 area % of the upper surface 916. For example, in some embodiments, the inorganic dielectric layer 914 can represent between 50% and 99% of the surface area of the upper surface 916, between the 60% and 99% of the surface area of the upper surface 916, between the 60% and 80% of the surface area of the upper surface 916, between the 80% and 99% of the surface area of the upper surface 916, between the 90% and 99% of the surface area of the upper surface 916, or a value in a range defined by any of these values. In some embodiments, the amount of the surface area of the upper surface 916 that the inorganic dielectric layer 914 makes up can depend upon the density and pitch of the TSVs 904. In general, the greater the inorganic proportion of the dielectric field region of the upper surface 916, the stronger the direct bond.

The inorganic dielectric layer 914, the organic dielectric layer 910, and the TSVs 904 can be planarized using any suitable planarization process. For example, in some embodiments, the planarization process comprises a CMP process that involves using a polishing pad and a slurry to polish the inorganic dielectric layer 914, the organic dielectric layer 910, and the TSVs 904 to form the upper surface 916. Additionally, unlike in conventional damascene processes where copper overburden from plating is to be removed, the CMP process need not remove significant amounts of copper as part of the planarization and can be performed with a single polishing pad and a single slurry chemistry. After performing the CMP process using the single polishing pad and the single slurry chemistry, the top surface of the TSVs 904 can be recessed below the top surface of the inorganic dielectric layer 914, particularly where the upper surface 916 is to serve as a hybrid bonding surface.

At block 810, after planarizing the inorganic dielectric layer 914, the organic dielectric layer 910, the TSVs 904, and forming the bonding layer 918 and the bonding surface 916, the upper surface 916 can be prepared for hybrid bonding. In some embodiments, preparing the bonding surface 916 for hybrid bonding comprises polishing the bonding surface 916, activating the bonding surface 916, terminating bonding surface 916 with a chemically active species, rinsing the bonding surface 916, and/or drying the chemically active surface. In other embodiments, preparation can include only sufficient polishing of the upper surface 916, and the other surface to be hybrid bonded can be activated and/or terminated.

After preparing the upper surface 916 for hybrid bonding, the element 900 can undergo additional processing, such as hybrid bonding a second element to the bonding surface 916, thinning, singulation, etc.

### Additional Examples

According to one aspect, a method of forming a microelectronic component is provided. The method includes providing a substrate, forming a metal feature over the substrate, forming an organic dielectric layer over the element such that the organic dielectric layer covers sidewalls of the metal feature, forming an inorganic dielectric layer over the organic dielectric layer, and planarizing the inorganic dielectric layer, the organic dielectric layer, and the metal feature to form a hybrid bonding surface. The metal feature is exposed at the hybrid bonding surface.

In some embodiments, the inorganic dielectric layer provides at least 50 area % of the hybrid bonding surface. In some embodiments, the substrate includes a field dielectric and forming the organic dielectric layer over the element includes forming the organic dielectric layer such that a horizontal portion of the organic dielectric layer covers at least a portion of the field dielectric. In some embodiments, the horizontal portion of the organic dielectric layer has a first thickness over the field dielectric and, before its planarized, the metal feature has a second thickness over the field dielectric that is at least 1 μm greater than the first thickness. In some embodiments, the metal feature includes a first metal feature and the method also includes forming a second metal feature over the substrate, where the first and second metal features are spaced apart from each other by a gap, where forming the organic dielectric layer over the element includes forming the organic dielectric layer such that the organic dielectric layer covers sidewalls of the second metal feature, and where the inorganic dielectric layer fills the gap. In some embodiments, the organic dielectric layer lines the metal features. In some embodiments, the inorganic dielectric layer includes silicon oxide. In some embodiments, the inorganic dielectric layer includes multiple layers of different inorganic materials. In some embodiments, the inorganic dielectric layer includes two or more inorganic dielectric materials.

In another aspect, a microelectronic component is provided. The microelectronic component includes a substrate, a metal feature having sidewalls, an organic dielectric layer over the substrate and lining the sidewalls of the metal feature, an inorganic dielectric layer on the organic dielectric layer. The metal feature, the organic dielectric layer, and the inorganic dielectric layer form a hybrid bonding surface.

In some embodiments, the inorganic dielectric layer includes an inorganic dielectric material and the inorganic dielectric material makes up at least 50 area % of the hybrid bonding surface. In some embodiments, the inorganic dielectric material includes silicon oxide. In some embodiments, the organic dielectric layer includes a horizontal portion formed over the substrate and the inorganic dielectric layer covers the horizontal portion of the organic dielectric material. In some embodiments, the horizontal portion of the organic dielectric layer is not exposed at the hybrid bonding surface. In some embodiments, the metal feature includes a first metal feature, the hybrid bonding surface includes surfaces of the first metal feature and a second metal feature, the organic dielectric layers is formed over sidewalls of the second metal feature, the first and second metal features are spaced apart from each other by a gap, and the organic dielectric layer partially fills the gap. In some embodiments, the organic dielectric layer lines the first and second metal features. In some embodiments, the inorganic dielectric layer partially fills the gap.

In another aspect a method of forming a microelectronic component is provided. The method includes providing an element having a through-semiconductor via (TSV) protruding from a semiconductor surface, where the TSV includes a metallic main conductor portion. The method further includes forming an organic dielectric layer over the element such that the organic dielectric layer covers sidewalls of the TSV, forming an inorganic dielectric layer over the organic dielectric layer, planarizing the inorganic dielectric layer, the organic dielectric layer, and the TSV to expose the main conductor portion.

In some embodiments, planarizing the inorganic dielectric layer, the organic dielectric layer, and the TSV include planarizing the inorganic dielectric layer, the organic dielectric layer, and the TSV to form a hybrid bonding surface, the main conductor portion is exposed at the hybrid bonding surface. In some embodiments, the TSV includes a and a TSV liner that extends around the main conductor portion. In some embodiments, the TSV liner includes an inorganic dielectric material. In some embodiments, the TSV liner includes a conductive barrier layer. In some embodiments, the conductive barrier layer includes one or both of titanium and tantalum. In some embodiments, the inorganic dielectric material includes a first inorganic dielectric material and the inorganic dielectric layer includes a second inorganic dielectric material that is different than the first inorganic dielectric material. In some embodiments, the inorganic dielectric layer includes the inorganic dielectric material. In some embodiments, the inorganic dielectric material includes silicon oxide.

In another aspect, a microelectronic component is provided. The microelectronic component includes an element having a through-semiconductor via (TSV) having a portion that protrudes from a surface of the element, an organic dielectric material over the surface of the element and lining the portion of the TSV, and an inorganic dielectric material on the organic dielectric material. The metal feature, the organic dielectric layer, and the inorganic dielectric layer form an upper surface.

In some embodiments, the upper surface includes a hybrid bonding surface. In some embodiments, the organic dielectric material does not line a portion of the TSV embedded below the semiconductor surface.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of forming a microelectronic component, the method comprising:
providing a substrate;
forming a metal feature over the substrate;
forming an organic dielectric layer over the substrate such that the organic dielectric layer covers sidewalls of the metal feature;
forming an inorganic dielectric layer over the organic dielectric layer; and
planarizing the inorganic dielectric layer, the organic dielectric layer, and the metal feature to form a hybrid bonding surface, wherein the metal feature is exposed at the hybrid bonding surface.

2. The method of claim 1, wherein the inorganic dielectric layer provides at least 50% area of the hybrid bonding surface.

3. The method of claim 1, wherein the substrate comprises a field dielectric and wherein forming the organic dielectric layer over the substrate comprises forming the organic dielectric layer such that a horizontal portion of the organic dielectric layer covers at least a portion of the field dielectric.

4. The method of claim 3, wherein the horizontal portion of the organic dielectric layer has a first thickness over the field dielectric, wherein, before planarization, the metal feature has a second thickness over the field dielectric, and wherein the second thickness is at least 1 μm greater than the first thickness.

5. The method of claim 1, wherein the metal feature comprises a first metal feature, the method further comprising:
forming a second metal feature over the substrate, wherein the first and second metal features are spaced apart from each other by a gap, wherein forming the organic dielectric layer over the substrate comprises forming the organic dielectric layer such that the organic dielectric layer covers sidewalls of the second metal feature, and wherein the inorganic dielectric layer fills the gap.

6. The method of Claim 5, wherein the organic dielectric layer lines the metal features.

7. The method of claim 1, wherein the inorganic dielectric layer comprises silicon oxide.

8. The method of claim 1, wherein the inorganic dielectric layer comprises multiple layers of different inorganic materials.

9. The method of claim 1, wherein the inorganic dielectric layer comprises two or more inorganic dielectric materials.

10. A microelectronic component, comprising:
a substrate;
a metal feature having sidewalls;
an organic dielectric layer over the substrate and lining the sidewalls of the metal feature; and
an inorganic dielectric layer on the organic dielectric layer, wherein the metal feature, the organic dielectric layer, and the inorganic dielectric layer form a hybrid bonding surface.

11. The microelectronic component of claim 10, wherein the inorganic dielectric layer comprises an inorganic dielectric material and wherein the inorganic dielectric material makes up at least 50% area of the hybrid bonding surface.

12. The microelectronic component of claim 11, wherein the inorganic dielectric material comprises silicon oxide.

13. The microelectronic component of claim 10, wherein the organic dielectric layer comprises a horizontal portion formed over the substrate and wherein the inorganic dielectric layer covers the horizontal portion of the organic dielectric layer.

14. The microelectronic component of claim 13, wherein the horizontal portion of the organic dielectric layer is not exposed at the hybrid bonding surface.

15. The microelectronic component of claim 10, wherein the metal feature comprises a first metal feature, wherein the hybrid bonding surface comprises surfaces of the first metal feature and a second metal feature, wherein the organic dielectric layer is formed over sidewalls of the second metal feature, wherein the first and second metal features are spaced apart from each other by a gap, and wherein the organic dielectric layer partially fills the gap.

16. The microelectronic component of claim 15, wherein the organic dielectric layer lines the first and second metal features.

17. The microelectronic component of claim 15, wherein the inorganic dielectric layer partially fills the gap.

18. (canceled)

19. (canceled)

20. (canceled)

21. (canceled)

22. (canceled)

23. (canceled)

24. (canceled)

25. (canceled)

26. (canceled)

27. A microelectronic component, comprising:
an element having a through-semiconductor via (TSV) having a portion that protrudes from a surface of the element;
an organic dielectric material over the surface of the element and lining the portion of the TSV; and
an inorganic dielectric material on the organic dielectric material, wherein the TSV, the organic dielectric material, and the inorganic dielectric material form an upper surface.

28. The microelectronic component of claim 27, wherein the upper surface comprises a hybrid bonding surface.

29. The microelectronic component of claim 27, wherein the organic dielectric material does not line a portion of the TSV embedded below the upper surface.
